(19) United States
(12) Patent Application Publication
(10) Pub. No.: US 2026/0202467 A1
(43) Pub. Date: Jul. 16, 2026

(54) IMPEDANCE CONTROL STACK-UP STRUCTURE ON NON-CONDUCTIVE SUBSTRATE FOR HIGH-PERFORMANCE PROBING AND METHODS OF FORMING THE SAME

(71) Applicant: Taiwan Semiconductor Manufacturing Company Limited, Hsinchu (TW)

(72) Inventors: Shao-Yu WANG, Hsinchu City (TW); Kai-Yi TANG, New Taipei City (TW); Guang-Sing HUANG, Hsinchu (TW); Kuan Chun CHEN, Hsinchu City (TW); Shu An SHANG, Kaohsiung City (TW)

(21) Appl. No.: 19/016,015

(22) Filed: Jan. 10, 2025

(51) Int. Cl. G01R 31/28

(52) U.S. Cl. CPC G01R 31/2886

(57) ABSTRACT

The present disclosure relates to a semiconductor structure formed on a non-conductive substrate designed for high-performance probing in semiconductor testing applications. The semiconductor structure comprises multiple metal and dielectric layer, integrated passive devices (IPDs), and GND (ground) shielding layers to ensure precise control of signal impedance and minimize electromagnetic interference (EMI) during high-frequency testing. The structure includes a vertically connected metal core through a via structure surrounded by barrier dielectrics, allowing vertical interconnection between signal layers while preventing crosstalk. Additionally, guide holes plated with conductive metals establish shorted paths for loopback needles, thereby providing shortened loopback path for enhanced signal transmission and high-frequency operation. The design further incorporates LC devices (capacitors and inductors) embedded within the stack-up, facilitating signal modulation and power distribution. The integrated system supports stable and efficient high-frequency operations, offering enhanced signal integrity and performance reliability during probe testing of semiconductor devices.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area.

As semiconductor devices evolve and move towards higher integration densities, there is an increasing demand for precise signal integrity during high-frequency testing, particularly in probe testing systems. In related probe card architectures, impedance mismatches and electromagnetic interference (EMI) often occur, leading to signal degradation and poor testing results. These issues are exacerbated as testing frequencies increase and circuit complexities grow.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a vertical cross-sectional view of a portion of a circuit probe test system that may be used to perform circuit probe testing, such as loopback testing, of a device under test (DUT) according to various embodiments of the present disclosure.

FIG. 2 illustrates a vertical cross-sectional view of the intermediate impedance control stack-up structure used for impedance control on ceramic plate dies to form the circuit probe test system.

FIG. 3A. illustrates a vertical cross-sectional view of the intermediate impedance control stack-up structure before placement of integrated passive device (IPD).

FIG. 3B. illustrates a top-down view of the intermediate impedance control stack-up structure as illustrated in FIG. 3A.

FIG. 3C illustrates a bottom-up view of the intermediate impedance control stack-up structure as illustrated in FIG. 3A.

FIG. 4A illustrates a vertical cross-sectional view of the intermediate impedance control stack-up structure after placement of integrated passive device (IPD).

FIG. 4B. illustrates a top-down view of the intermediate impedance control stack-up structure as illustrated in FIG. 4A.

FIG. 4C illustrates a bottom-up view of the intermediate impedance control stack-up structure as illustrated in FIG. 4A.

FIG. 5A illustrates a vertical cross-sectional view of the intermediate impedance control stack-up structure after via etch.

FIG. 5B. illustrates a top-down view of the intermediate impedance control stack-up structure as illustrated in FIG. 5A.

FIG. 5C shows a bottom-up view of the intermediate impedance control stack-up structure as illustrated in FIG. 5A.

FIG. 6A illustrates a vertical cross-sectional view of the intermediate impedance control stack-up structure after via barrier deposition.

FIG. 6B. illustrates a top-down view of the intermediate impedance control stack-up structure as illustrated in FIG. 6A.

FIG. 6C illustrates a bottom-up view of the intermediate impedance control stack-up structure as illustrated in FIG. 6A.

FIG. 7A illustrates a vertical cross-sectional view of the intermediate impedance control stack-up structure after an integrated passive device (IPD) contact opening.

FIG. 7B. illustrates a top-down view of the intermediate impedance control stack-up structure as illustrated in FIG. 7A.

FIG. 7C illustrates a bottom-up view of the intermediate impedance control stack-up structure as illustrated in FIG. 7A.

FIG. 8A illustrates a vertical cross-sectional view of the intermediate impedance control stack-up structure after metal deposition to fill via and to connect IPD.

FIG. 8B. illustrates a top-down view of the intermediate impedance control stack-up structure as illustrated in FIG. 8A.

FIG. 8C illustrates a bottom-up view of the intermediate impedance control stack-up structure as illustrated in FIG. 8A.

FIG. 9A illustrates a vertical cross-sectional view of the impedance control stack-up structure after metal trace formation for IPD.

FIG. 9B. illustrates a top-down view of the impedance control stack-up structure as illustrated in FIG. 9A.

FIG. 9C illustrates a bottom-up view of the impedance control stack-up structure as illustrated in FIG. 9A.

FIG. 10A illustrates a vertical cross-sectional view of the impedance control stack-up structure after forming a metal trace for an IPD.

FIG. 10B illustrates a detailed view of a via structure of the impedance control stack-up structure after metal trace formation for IPD as illustrated in FIG. 10A.

FIG. 11A illustrates a vertical cross-sectional view of the intermediate metal line formation on ceramic plate dies for an integrated probe head.

FIG. 11B illustrates a top-down view of the intermediate integrated probe head formation as illustrated in FIG. 11A.

FIG. 11C illustrates a bottom-up view of the intermediate integrated probe head formation as illustrated in FIG. 11A.

FIG. 12A illustrates a vertical cross-sectional view of the intermediate integrated probe head after etching a ground (GND) shielding trench through a ceramic place for the integrated probe head formation.

FIG. 12B illustrates a top-down view of GND shielding trench etch for the intermediate integrated probe head formation as illustrated in FIG. 12A.

FIG. 12C illustrates a bottom-up view of the intermediate integrated probe head formation as illustrated in FIG. 12A.

FIG. 13A illustrates a vertical cross-sectional view of the intermediate integrated probe head after forming a GND shielding layer through a ceramic place for an integrated probe head.

FIG. 13B illustrates a top-down view of GND metal layer deposition for the intermediate integrated probe head formation as illustrated in FIG. 13A.

FIG. 13C illustrates a bottom-up view of the intermediate integrated probe head formation as illustrated in FIG. 13A.

FIG. 14A illustrates a vertical cross-sectional view of the intermediate integrated probe head after forming a GND metal layer trace on each side of ceramic plate dies for an integrated probe head.

FIG. 14B illustrates a top-down view of a GND metal layer trace formation for the intermediate integrated probe head formation as illustrated in FIG. 14A.

FIG. 14C illustrates a bottom-up view of a GND metal layer trace formation for the intermediate integrated probe head formation as illustrated in FIG. 14A.

FIG. 15A illustrates a vertical cross-sectional view of the intermediate integrated probe head after forming a dielectric layer on each side of ceramic plate dies for an integrated probe head.

FIG. 15B illustrates a top-down view of shows a dielectric layer formation for the integrated probe head formation as illustrated in FIG. 15A.

FIG. 15C illustrates a bottom-up view of shows a dielectric layer formation for the intermediate integrated probe head formation as illustrated in FIG. 15A.

FIG. 16A illustrates a vertical cross-sectional view of the intermediate integrated probe head after placing a capacitor on a metal trace for an integrated probe head.

FIG. 16B illustrates a top-down view of the intermediate integrated probe head formation as illustrated in FIG. 16A.

FIG. 16C illustrates a bottom-up view of a metal trace for a capacitor placement of the intermediate integrated probe head formation as illustrated in FIG. 16A.

FIG. 17A illustrates a vertical cross-sectional view of the intermediate integrated probe head after etching an oxide trench and depositing a GND shielding layer barrier dielectric formation for an integrated probe head.

FIG. 17B illustrates a top-down view of an oxide trench etch for the intermediate integrated probe head formation as illustrated in FIG. 17A.

FIG. 17C illustrates a bottom-up view of the intermediate integrated probe head formation as illustrated in FIG. 17A.

FIG. 18A illustrates a vertical cross-sectional view of the intermediate integrated probe head after placing an inductor and forming a metal layer trace for an integrated probe head.

FIG. 18B illustrates a top-down view of a metal trace formation for an inductor placement of the intermediate integrated probe head formation as illustrated in FIG. 18A.

FIG. 18C illustrates a bottom-up view of the intermediate integrated probe head formation as illustrated in FIG. 18A.

FIG. 19A illustrates a vertical cross-sectional view of the integrated probe head after forming a GND shielding layer structure.

FIG. 19B illustrates a detailed view of the integrated probe head after forming a GND shielding layer structure as illustrated in FIG. 19A.

FIG. 20 illustrates vertical cross-sectional view of an integrated probe head with loopback needles.

FIG. 21 illustrates a perspective view of a guide hole plated with metal in ceramic plate dies.

FIG. 22 shows a perspective view of an integrated probe head, illustrating the arrangement of loopback needles and related components.

FIG. 23 is a process flow illustrating embodiment method steps to form an impedance stack-up structure, according to various embodiments disclosed herein.

FIG. 24 is a process flow illustrating embodiment method steps to form an impedance stack-up structure with IPD, according to various embodiments disclosed herein.

FIG. 25 is a process flow illustrating embodiment method steps to form an integrated probe head with an impedance stack-up structure, according to various embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. Generally, all devices of the present disclosure may be rotated unless otherwise specified, and the spatially relative descriptors used herein may likewise be interpreted accordingly. Unless explicitly stated otherwise, each element having the same reference numeral is presumed to have the same material composition and to have a thickness within a same thickness range.

The present disclosure is directed to an integrated probe head having an impedance control stack-up structure on a non-conductive substrate, suitable for high-performance applications such as probe testing in advanced semiconductor devices. Circuit probe testing is an essential step in the fabrication process of semiconductor devices, such as integrated circuits (ICs). Circuit probe testing provides early validation of the device's electrical functionality, often before wafer dicing or packaging, which can lead to significant cost savings. However, circuit probe testing presents technical challenges as high-performance applications operate under high-frequency signals. In instances during which complex semiconductor devices may be tested, impedance mismatches and electromagnetic interference (EMI) often occur, leading to signal degradation and poor testing results. These issues may be exacerbated as testing frequencies increase and circuit complexities grow. These high-performance applications require precise control of impedance to ensure signal integrity during high-frequency testing.

Accordingly, there is a desire for improvements in circuit probe test systems to provide enhanced signal integrity (SI) and impedance control during high-frequency loopback testing of a device under test (DUT). Various embodiments of the present disclosure may include the implementation of an impedance control stack-up structure in an integrated probe head to address these challenges. This stack-up structure may comprise a combination of metal layers, dielectric layers, and ground shielding, which may be applied to a probe card for improved performance. The impedance control stack-up structure may be formed on a non-conductive substrate, such as ceramic plate dies. The impedance control stack-up structure disclosed herein addresses these challenge by embedding integrated passive devices (IPDs) and capacitors and inductors devices (commonly referred to as LC devices), and using ground (GND) shielding to minimize electromagnetic interference (EMI). Other related signal routing schemes, which do not incorporate such impedance control features, face hurdles in maintaining performance and scalability as semiconductor technology advances to smaller feature sizes and higher frequencies.

Various embodiments testing probe cards are disclosed herein that provide precise control of capacitance and impedance during signal transmission by using an impedance control stack-up structure comprising metal and dielectric layers. The various embodiments structures may also mitigate EMI and ensure high signal integrity by embedding ground shielding layers and integrated passive devices (IPDs) such as capacitors and inductors.

Various embodiment integrated probe heads disclosed herein may include a probe card that may include a substrate portion positioned above a sophisticated probe head. The probe head may be integrated with inductor and capacitor components (LC components), GND shielding layer, conductive traces electrically coupling loopback needles with a metal plated guide hole. The plated metal in the guide hole may provide a direct electrical connection between the loopback needles and the conductive traces, effectively shortening the loopback signal path and minimizing signal degradation. Metal traces may also be strategically routed to minimize the signal path length and, therefore, reduce signal degradation typically seen with longer paths.

The various embodiment integrated probe heads disclosed herein may include an impedance control stack-up structure, which may include several layers of conductive and dielectric materials, along with embedded integrated passive devices (IPDs). These IPDs may be configured to tune the electrical properties of the probe head, enabling the probe head to maintain signal integrity even under the stress of high-frequency operations. The arrangement of these various components within the stack-up structures ensures a tailored impedance profile that may match the requirements of the various testing environments.

Moreover, the entire assembly of those components may be a part of an integrated probe head structure. This integrated probe head structure may be designed and engineered to include the various components in a compact and efficient layout, enhancing the overall functionality and effectiveness of the probe system and allowing a seamless interaction between the conductive traces, IPDs, loopback needles coupled by the metal plated guide hole, and DUT. The enhanced design of various embodiments may address previous deficiencies by improving the electromagnetic compatibility and reducing interference, thereby supporting more accurate and repeatable testing outcomes. The embodiments disclosed herein not only push the boundaries of probe testing capabilities but also set a new standard for the design and implementation of probe cards in the semiconductor testing industry.

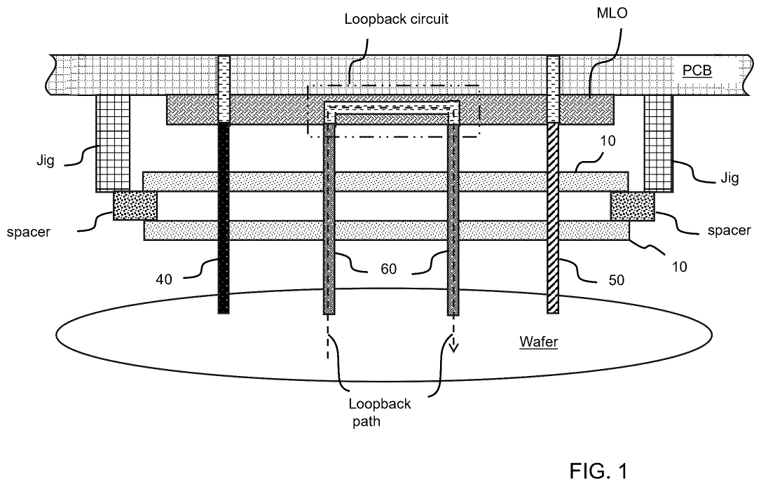

FIG. 1 illustrates a circuit probe test system without the impedance control stack-up structure implemented, showing the basic configuration used for testing a device under test (DUT) (e.g., wafer). The probe card includes a probe head with multiple probe needles 40, 50, 60 that make contact with the DUT's contact pads. These needles (40, 50, 60) transmit test signals to the DUT and receive response signals. FIG. 1 includes a multi-layer organic (MLO) circuit and a printed circuit board (PCB), which function as the primary signal routing interface for the probe system.

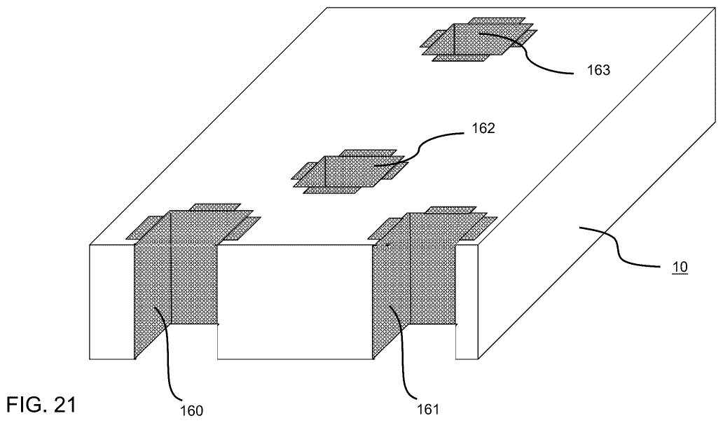

Spacers and jigs are used to provide mechanical support, ensuring the alignment of the components during testing. Guide holes 160 (not shown in FIG. 1, but shown in FIG. 21) in the ceramic plate dies 10 allow the insertion of various probes, such as the GND needle 40, the power needle 50, and the loopback needle 60. The loopback needle 60 is a conduit for enabling loopback testing, in which signals are routed from one part of the DUT back to another to verify communication and signal integrity within the DUT itself.

At the bottom of the structure, the wafer represents the DUT being tested. In this basic configuration, signals travel through the loopback path, and feedback signals are analyzed to assess the functionality of the DUT. However, impedance control and signal integrity challenges, such as signal degradation and electromagnetic interference (EMI), can still occur due to the lack of advanced impedance management in this setup.

This configuration, shown in FIG. 1, represents a probe system prior to the implementation of the impedance control stack-up structure. Since a high frequency signal travels a long loopback path through a loopback needle, loopback circuits on MLO, back to loopback needle again, the system, as a result, may face signal integrity (SI) challenges during high-frequency loopback testing due to long signal paths and interference from adjacent signal lines, both of which can degrade the transmitted signals.

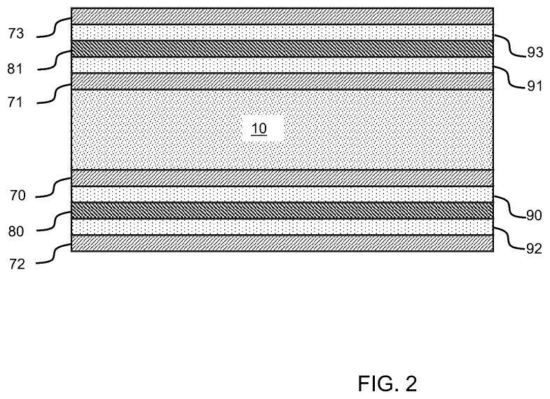

FIG. 2 illustrates a cross-sectional view of the impedance control stack-up structure (referred to hereafter as the ‘stack-up structure’) designed to manage signal integrity and impedance. The impedance control stack-up structure may be built on ceramic plate dies 10, either an upper die (UD) or lower die (LD) ceramic plate as described in FIG. 1. Within this stack-up structure, conductive layers 70, 71, 72, 73 may be composed of conductive materials, but are not limited to, such as copper or tungsten, though other conductive materials may also be used. These conductive layers may transfer electrical signals or power. The metal trace design of conductive layers 70, 71, 72,73 may be configured to route signals and deliver power between different parts of the probe system. Alternatively, the metal trace design of conductive layers may be configured to modulate capacitance and impedance of stack-up structure by adjusting overlap of two conductive layers. The multiple conductive layers 70, 71, 72, 73 ensure efficient electrical transmission, while maintaining proper power distribution across the stack-up structure.

Dielectric layers 90, 91, 92, 93 may be positioned between the conductive layers (70,71,72,73) and ground metal layers (GND) 80, 81. The material properties of dielectric layers 90, 91, 92, 93, both dielectric constants and thicknesses, may be configured to modulate impedance control through the stack-up system resulting in impedance between about 30 Ω to about 100 Ω, about 40 Ω to about 90 Ω, or about 50 Ω to about 80 Ω. The equation for capacitance (C) is C=ε₀*εᵣ*A/d, where C is the capacitance in farads (F), ε₀ is the permittivity of free space (approximately 8.854*10⁻¹² F/m), εᵣ is the relative permittivity (or dielectric constant) of the material, A is the area of the plates, and d is the distance (or thickness) between the plates. For example, SiO₂ dielectric constant may be in the range of 3.9-4.2. The dielectric constant of Si₃N₄ may be in the range of 7-8. SiCOH's dielectric constant may be in the range of 2.7-3.1. SiLK (low-k polymer dielectric) may have as low as 2.65. Polyimide's dielectric constant may be in the range of 2.8-3.5. In some embodiment in which SiLK may be used, dielectric thickness may be further scaled down compared to that of SiO₂, for given capacitance requirement. In another embodiment in which SiO₂ may be used, dielectric thickness may be between about 1 mm to about 50 mm, about 3 mm to about 40 mm, or about 5 mm to about 30 mm. The dielectric thickness may be thicker than that of SiLK for given capacitance requirement, but SiO₂ with given thickness may possess lower leakage property than that of SiLK, thereby reducing potential interference or signal error. Alternatively, dielectric layers 90, 91, 92, 93 may also provide electrical insulation, preventing unintended short circuits between the conductive layers.

GND (ground) metal layers 80/81 serve as reference points for electrical potential and may be configured to reduce electromagnetic interference (EMI). By grounding the stack-up structure, the GND metal layers 80, 81 may shield the conductive layers (70, 71, 72, 73) thereby improving overall signal integrity. The placement of the GND metal layers (80, 81) on both the upper and lower side of ceramic plate dies 10 ensures comprehensive EMI mitigation throughout the structure.

The integration of conductive layers 70, 71, 72, 73, dielectric layers 90, 91, 92, 93, and GND metal layers 80, 81, along with their respective metal trace designs, results in a highly efficient impedance control stack-up structure. For example, the effective overlap area (‘A’ of capacitance equation) of a pair of metal layers may be configured to modulate capacitance, thereby changing impedance of the stack-up structure. This configuration, by adjusting the effective overlap area of the metal traces, may minimize signal degradation and maintain the accuracy required for probe testing at high frequencies ensuring reliable and high-performance testing environments.

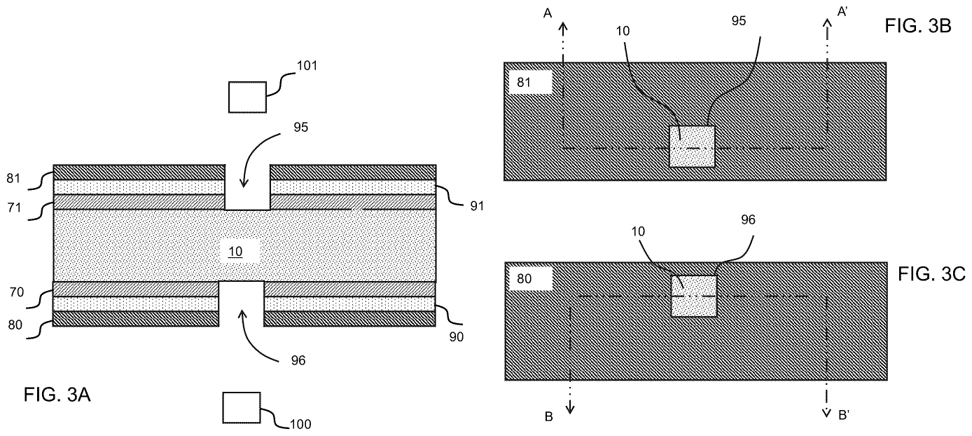

FIG. 3A illustrates a vertical cross-sectional view of the intermediate impedance control stack-up structure, taken along the A-A′ axis of FIG. 3B and the B-B′ axis of FIG. 3C. The stack-up structure is built on the ceramic plate dies 10, which serves as the base frame for the entire structure. Following GND metal layers (80, 81) deposition and patterning for IPD (100, 101), etching may be performed, but are not limited to, with wet chemical etch, dry etch, or laser ablation. In some embodiment in which copper is used as metal, Ferric Chloride (FeCl₃) may be used to etch copper. For oxide etch, HF or BOE may be used to etch oxide without attacking metal like copper. Alternatively, plasma dry etching may also be used to etch oxide and copper, and laser ablation may be another. The etching of the stack-up structure creates openings (95, 96) to accommodate the IPD 100 and 101. IPD 100 and 101, when placed into the etched openings (95, 96), are integrated within the stack-up to modify or enhance electrical characteristics such as power integrity. This integrated power device (IPD), such as voltage regulators or power management ICs, may deliver stable power distribution by minimizing variations in power supply.

FIG. 3B illustrates a top-down view of the intermediate impedance control stack-up structure illustrated in FIG. 3A. FIG. 3B illustrates how the stack-up structure is etched to allow for the placement of IPD 101 in opening 95.

FIG. 3C illustrates a bottom-up view of the intermediate impedance control stack-up structure illustrated in FIG. 3A. FIG. 3C illustrates the location in which IPD 100 is placed in the opening 96 created through the etching process.

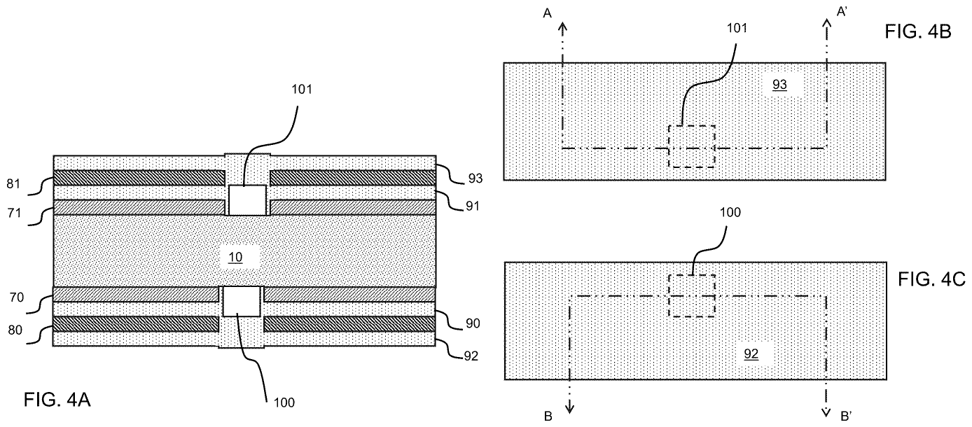

FIG. 4A illustrates a cross-sectional view after depositing the second dielectric (92, 93), following IPD 100 and 101 placement, taken along the A-A′ axis of FIG. 4B and the B-B′ axis of FIG. 4C. In some embodiments, the IPDs 100 and 101 may be integrated within an impedance control stack-up structures to enhance electrical characteristics such as power distribution and stability in high-frequency operations as explained in FIG. 3A. The dielectric (90, 91, 92, 93) materials chosen may serve various purposes including insulation between conductive layers, and impedance tuning based on the materials'dielectric constant and thickness. The various dielectric materials may be positioned over a first conductive layer (70, 71) and GND metal layers (80, 81), effectively controlling the impedance across the stack-up structure. For example, there may be a lower first conductive layer 70, lower GND metal layer 80 and upper first conductive layer 71, and upper GND metal layer 81.

The dielectric constant (k) of the materials used for dielectric (90, 91, 92, 93) may play a role in determining the capacitance between the metal layers. By selecting dielectric materials with varying dielectric constants, the stack-up structure may tune impedance to match the signal transmission requirements of the system. Impedance matching may be obtained by choosing dielectric or changing thickness of dielectric or adjusting effective overlap area of metal layers'trace as explained above with reference to FIG. 2. Common materials for dielectric layers include, but are not limited to, silicon dioxide (SiO₂), silicon nitride (Si₃N₄), SiCOH, and polyimide, each offering different dielectric constants.

The thickness of the dielectric layers (90, 91, 92, 93) may also contributes to impedance control. For example, thinner dielectric layers may provide higher capacitance. In contrast, thicker dielectric layers may reduce capacitance. By modifying or selecting the dielectric material with a particular dielectric constant and/or modifying/selecting the thickness of the dielectric layer, a precise adjustment of the capacitance to control signal integrity and performance may be achieved.

FIG. 4B illustrates a top-down view of the embodiment in FIG. 4A after depositing dielectric 93 and gap fill over IPD 101. FIG. 4C provides a bottom-up view of the embodiment in FIG. 4A after depositing the lower second dielectric 92 and gap fill over IPD 100.

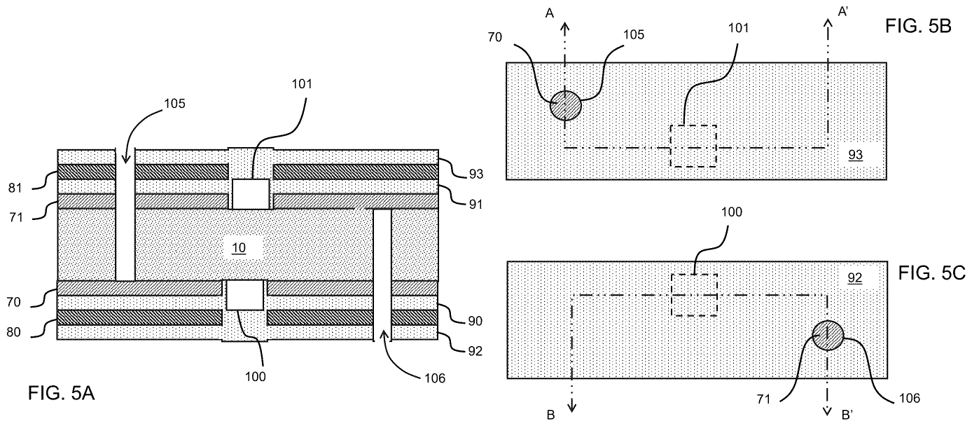

FIG. 5A illustrates a cross-sectional view of an embodiment of the intermediate impedance control stack-up structure after the via trench (105, 106) etching process. The via trenches 105 and 106 may be etched or drilled into ceramic plate dies 10 to later connect to the first conductive layers 70 and 71, respectively. The etching may be performed, but are not limited to, with plasma dry etch or laser ablation to etch oxide and copper. These via trenches (105, 106) may enable subsequent vertical electrical connections between the first conductive layers (70, 71) and other components in the stack-up structure.

FIG. 5B illustrates a top-down view of the embodiment in FIG. 5A, after etching the via trench 105 through the ceramic plate dies 10 to prepare for connection to the lower first conductive layer 70. FIG. 5C illustrates a bottom-up view of the embodiment in FIG. 5A, after etching the via trench 106 through the ceramic plate dies 10 to prepare for connection to the conductive layer 71. The via trenches 105 and 106 may ensure proper alignment and connectivity to the relevant first conductive layer (70, 71) by various designs.

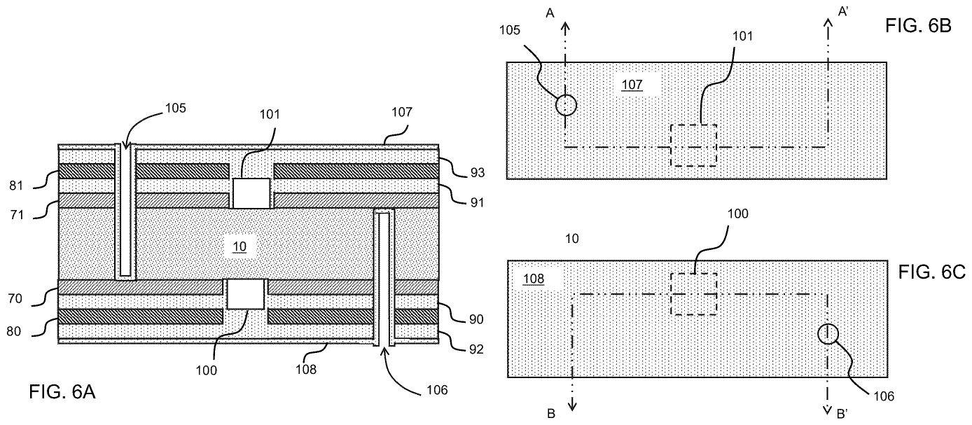

FIG. 6A illustrates a cross-sectional view of an embodiment of the intermediate impedance control stack-up structure after the oxide deposition (107, 108), which forms barriers within the via trenches (105, 106). The via trenches (105, 106) were previously etched through the ceramic plate dies 10 in FIG. 5. The oxide barriers (107, 108), more than 10 nm thick, serve to electrically isolate the via structures (105, 106) from surrounding conductive materials, ensuring proper signal and power routing through the first conductive layers 70 and 71, respectively.

FIG. 6B provides a top-down view of the embodiment in FIG. 6A, illustrating Via trench 105 after depositing the conformal oxide barrier 107. FIG. 6C provides a bottom-up view of the embodiment in FIG. 6A, illustrating Via trench 106 after depositing the conformal oxide barrier 108.

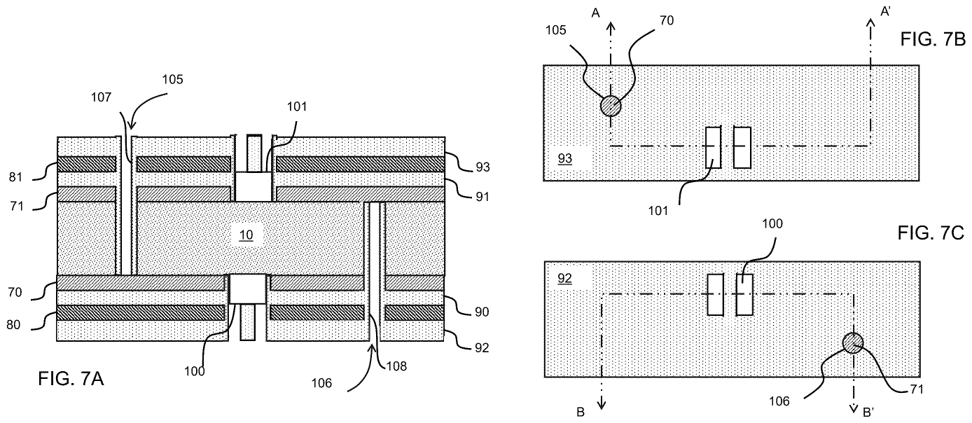

FIG. 7A illustrates a cross-sectional view of an embodiment of the intermediate impedance control stack-up structure after the anisotropic etch process into via trenches (105, 106) and IPD (100, 101) in which pre-defined patterning exists. The etching opens contact areas for the IPDs (100, 101) and the first conductive layers (70,71). The via trenches (105,106), previously formed with oxide barriers (107, 108), remain aligned with the corresponding first conductive layers (70, 71). The etch process allows for precise exposure of the contact regions, ensuring effective electrical connections between the IPDs and the first conductive layers (70, 71).

FIG. 7B provides a top-down view of the embodiment in FIG. 7A, illustrating the contact area exposed through the etching of via trench 105. The IPD 101 contact region is opened by removing dielectric 93 over IPD 101. FIG. 7C provides a bottom-up view of the embodiment in FIG. 7A, illustrating the contact area exposed through the etching of via trench 106. The IPD 100 contact region is opened by removing the lower second dielectric 92 over IPD 100, ensuring accessibility for forming electrical connections.

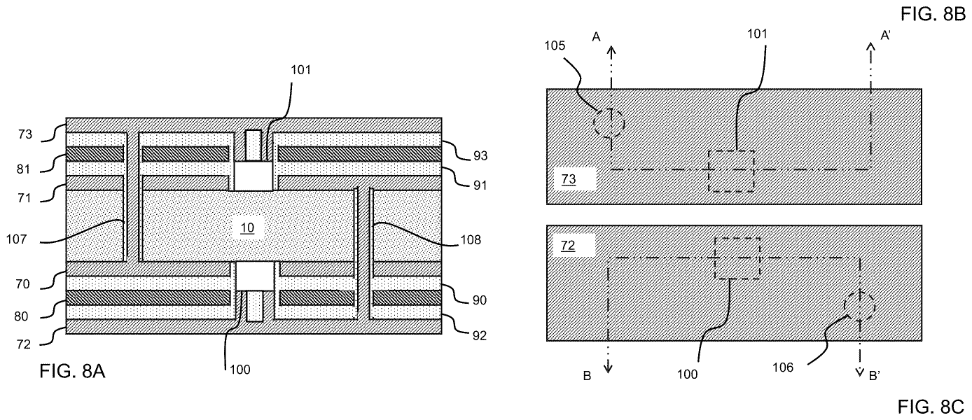

FIG. 8A illustrates a cross-sectional view of an embodiment of the intermediate impedance control stack-up structure after depositing the second conductive layers 72 and 73. For example, there may be a lower second conductive layer 72, and upper second conductive layer 73.

Alternatively, plating techniques may be used to form the second conductive layer (72, 73). Second conductive layers 72 and 73 are deposited into the via trenches (105, 106), as described in FIG. 7A, as well as the IPD (100, 101) contact regions. These second conductive layers (72, 73) form electrical connections between the first conductive layers (70, 71) and the IPDs (100, 101), ensuring electrical continuity through the vertical interconnects provided by the via trenches (105, 106) as shown in FIG. 7A.

FIG. 8B provides a top-down view of the embodiment in FIG. 8A, illustrating the second conductive layer (72, 73) fill into via trench 105 and the conformal deposition over the IPD 101. FIG. 8C provides a bottom-up view of the embodiment in FIG. 8A, illustrating the second conductive layer (72, 73) fill into Via trench 106 and the conformal deposition over the IPD 100.

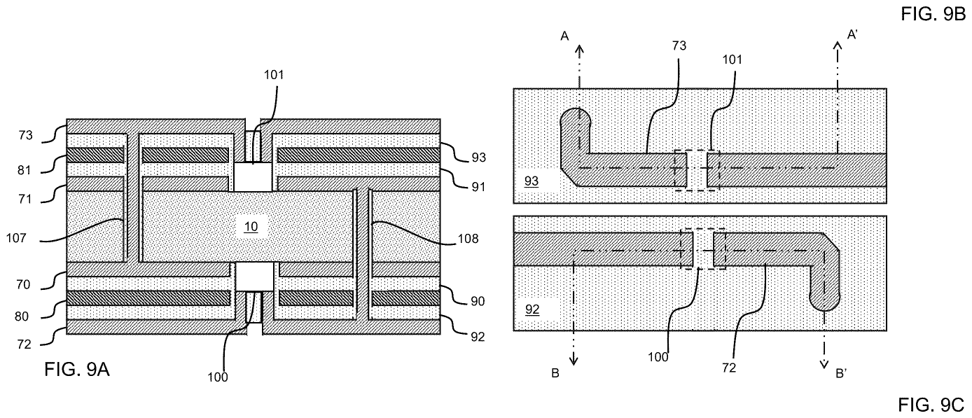

FIG. 9A illustrates a cross-sectional view of an embodiment of the impedance control stack-up structure after the formation of metal traces on the second conductive layer (72, 73). These traces may be patterned in various designs to form electrical pathways connecting IPDs (100, 101) to the corresponding conductive layers (71, 70). Alternatively, these traces may be configured to modulate capacitance by adjusting effective overlap area of inter-metal layers.

FIG. 9B provides a top-down view of the embodiment in FIG. 9A, showing the formation of the metal trace on conductive layer 73. The trace of conductive layer 73 connects the lower first conductive layer 70 to IPD 101, as depicted in FIG. 9A, establishing electrical continuity throughout the stack-up structure and ensuring signal or power routing. FIG. 9C provides a bottom-up view of the embodiment in FIG. 9A, illustrating the metal trace on the second conductive layer 72. The trace of the second conductive layer 72 (lower second conductive layer 72) connects the first conductive layer 71 (upper first conductive layer 71) to IPD 100 as shown in FIG. 9A, establishing electrical continuity throughout the stack-up structure and ensuring signal or power routing.

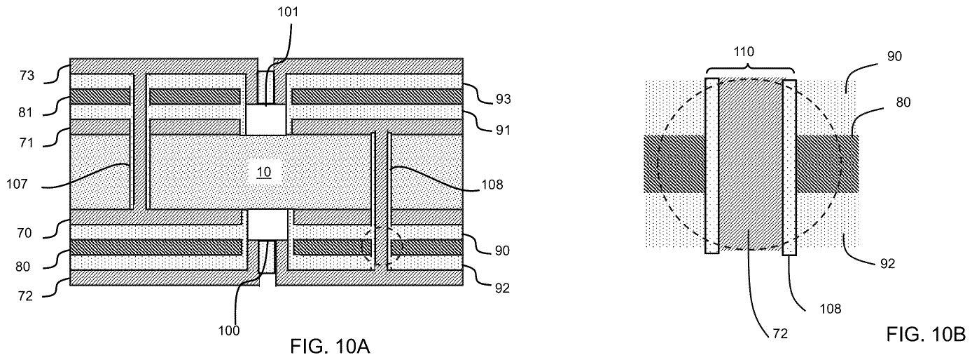

FIG. 10A illustrates a cross-sectional view of an embodiment of the impedance control stack-up structure, providing detailed look at the via structure 110, as described in FIG. 10B, and how it is insulated by a barrier dielectric 108 (107) from the surrounding metal layers.

FIG. 10B provides a zoomed-in view of via structure 110 composed of the lower second conductive layer 72 and barrier dielectric 108, showing how the barrier dielectric 108 is positioned between via core (also known as the second conductive layer 72) and the surrounding GND metal layer 80. The barrier dielectric 108 may form a protective layer, ensuring that the via structure 110 be insulated against other metal layers, thus maintaining the integrity of the signal or power being transmitted through via structure 110.

In some embodiment, IPD may be integrated into impedance control stack-up structure. By embedding integrated passive devices (IPDs), such as power regulators, directly within the stack-up structure, IPDs (100, 101) may enhance power distribution, stabilizing signal and reducing power fluctuations. For high frequency testing applications, the probe system industry faces increasing demands for improving signal integrity, power distribution, and impedance control as circuit complexity and operating frequencies increases. To resolve these challenges, the present disclosure of the impedance control stack-up structure, combined with strategic use of IPDs and via connecting scheme, ensures effective impedance control and EMI mitigation, providing a reliable solution for high-performance probe testing system.

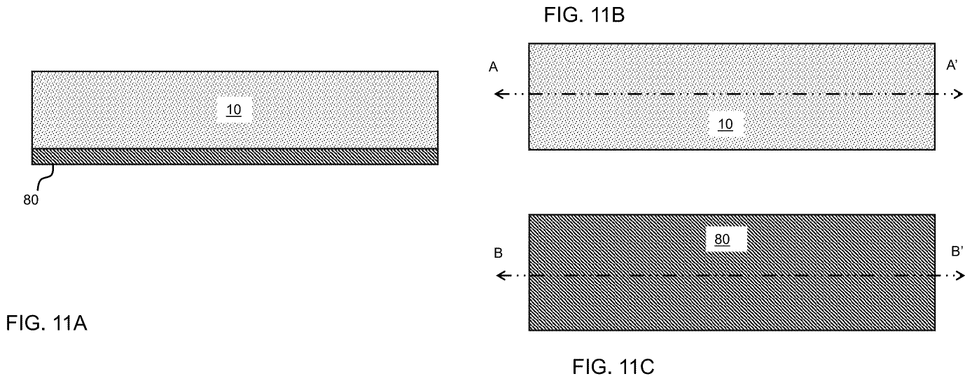

FIGS. 11A to 20 illustrate the sequential process to form integrated probe head structure.

FIG. 11A illustrates a cross-sectional view of the first stage of forming the intermediate integrated probe head, taken along the A-A′ axis of FIG. 11B and B-B′ axis of FIG. 11C. GND (ground) metal layer 80 is deposited onto the ceramic plate dies 10. GND metal layer 80 serves as a reference point for electrical potential and is configured to reduce electromagnetic interference (EMI).

FIG. 11B shows a top-down view of the ceramic plate dies 10. FIG. 11C provides a bottom-up view of the ceramic place and GND metal layer 80.

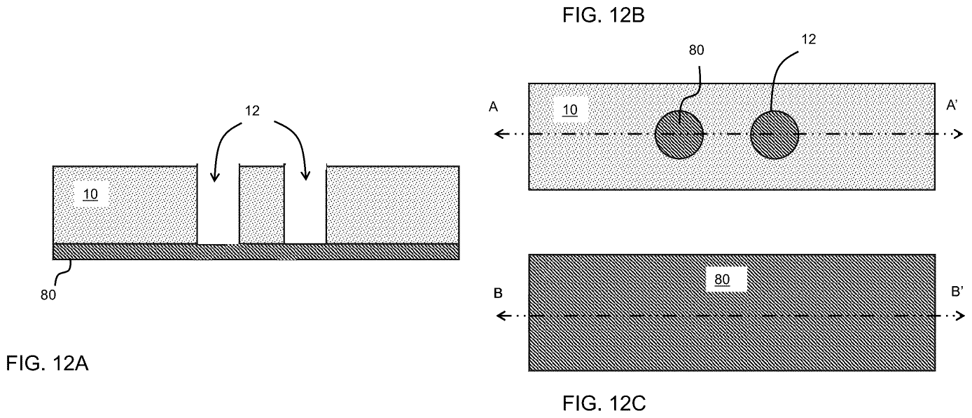

FIG. 12A shows a cross-sectional view of the ceramic plate dies 10, taken along the A-A′ axis of FIG. 12B and B-B′ axis of FIG. 12C, after etching through the ceramic plate dies 10 to form GND shielding trench 12. The etching may be performed, but are not limited to, with wet chemical etch, dry etch, or laser ablation.

FIG. 12B shows a top-down view of the ceramic plate dies 10 with etching patterns. FIG. 12C provides a bottom-up view of the ceramic plate dies 10 and GND metal layer 80.

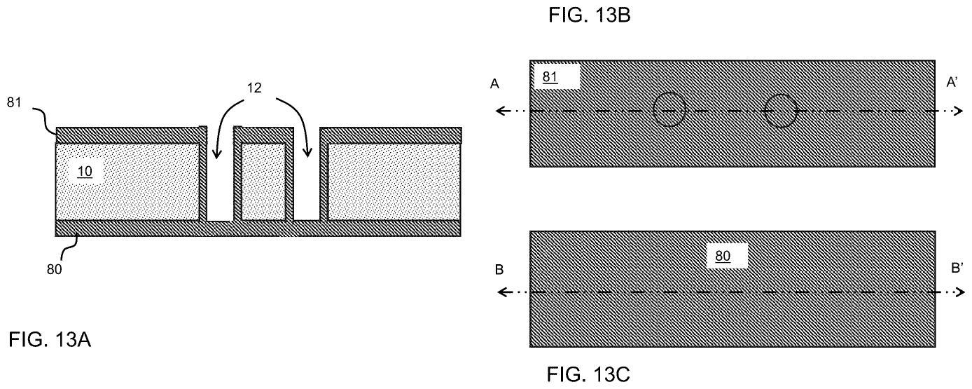

FIG. 13A shows a cross-sectional view of the ceramic plate dies 10, taken along the A-A′ axis of FIG. 13B and B-B′ axis of FIG. 13C, after depositing another GND metal layer 81 over the ceramic plate dies 10 and into GND shielding trench 12. FIG. 13B provides a top-down view of the ceramic plate dies 10 covered with GND metal layer 81. FIG. 13C provides a bottom-up view of the ceramic plate dies 10 with GND metal layer 80.

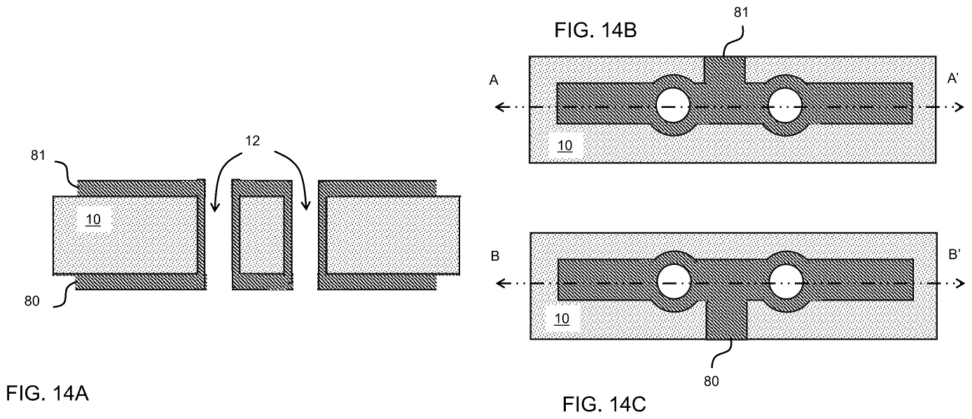

FIG. 14A shows a cross-sectional view of the ceramic plate dies 10, taken along the A-A′ axis of FIG. 14B and B-B′ axis of FIG. 14C, after further etching through GND shielding trench 12 with patterning of GND metal layer (80, 81) traces. The portions of GND metal layers 80 and 81 deposited within GND shielding trenches 12 form a GND shielding layer 120. The GND shielding layer (120), formed within the GND shielding trench (12), is connected to the GND metal traces (80, 81), establishing a continuous reference ground potential throughout the stack-up structure. By incorporating GND shielding layer 120 to GND metal layer 81 and 80 as a reference ground potential, the GND shielding layer 120 may prevent crosstalk, improving overall signal isolation. The GND shielding layer (120) is positioned to isolate sensitive signal from interference, ensuring signal integrity as they travel through the impedance control stack-up structure. GND shielding layer 120 may help mitigate EMI, ensuring that high-frequency signals experience minimal interference and achieving stable, low-noise signal transmission for high performance probing applications, where signal degradation and impedance mismatch may otherwise lead to testing inaccuracies

FIG. 14B provides a top-down view of the ceramic plate dies 10 after metal trace formation of GND metal layer 81. FIG. 14C provides a bottom-up view of the ceramic plate dies 10 after metal trace formation of GND metal layer 80.

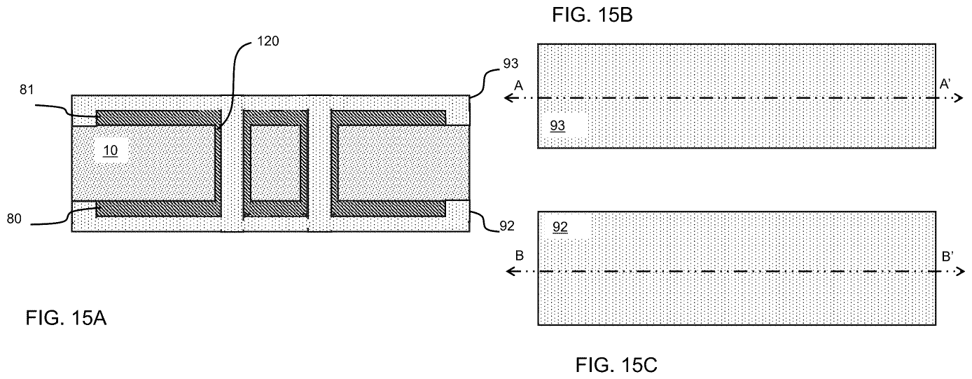

FIG. 15A shows a cross-sectional view of the ceramic plate dies 10, taken along the A-A′ axis of FIG. 15B and B-B′ axis of FIG. 15C, after depositing conformal second dielectrics (92, 93) over the metal trace of GND metal layer 80 and 81. The dielectric materials chosen may serve various purposes including insulation between conductive layers, and impedance tuning based on the materials'dielectric constant and thickness. The various dielectric materials may be positioned over GND metal layers (80, 81), effectively controlling the impedance across the stack-up structure.

The dielectric constant (k) of the materials used for second dielectrics 92 and 93 may play a role in determining the capacitance between the metal layers. By selecting dielectric materials with varying dielectric constants, the stack-up structure may tune impedance to match the signal transmission requirements of the system. Common materials for dielectric layers may include, but are not limited to, silicon dioxide (SiO₂), silicon nitride (Si₂N₄), SiCOH, and polyimide, each offering different dielectric constants. For example, SiO₂ dielectric constant may be in the range of 3.9-4.2. The dielectric constant of Si₃N₄ may be in the range of 7-8. SiCOH's dielectric constant may be in the range of 2.7-3.1. SiLK (low-k polymer dielectric) may have as low as 2.65. Polyimide's dielectric constant may be in the range of 2.8-3.5. In some embodiment in which SiLK may be used, dielectric thickness may be further scaled down compared to that of SiO₂, for given capacitance requirement. In another embodiment in which SiO₂ may be used, dielectric thickness may be thicker than that of SiLK for given capacitance requirement, but SiO₂ with given thickness may possess lower leakage property than that of SiLK, thereby reducing potential interference or signal error. Alternatively, Dielectric layers 90, 91, 92, 93 may also provide electrical insulation, preventing unintended short circuits between the conductive layers.

The thickness of the second dielectric layers (92, 93) may also contribute to impedance control, where thinner layers provide higher capacitance and thicker layers reduce capacitance, allowing for precise adjustment of signal integrity and performance.

FIG. 15B shows a top-down view of the intermediate integrated probe head structure after uniform deposition of dielectric 93. FIG. 15C shows a bottom-up view of the intermediate integrated probe head structure after uniform deposition of a lower second dielectric 92.

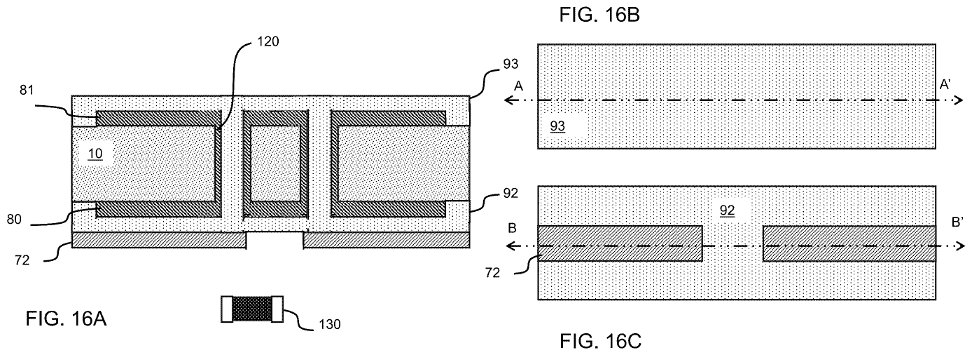

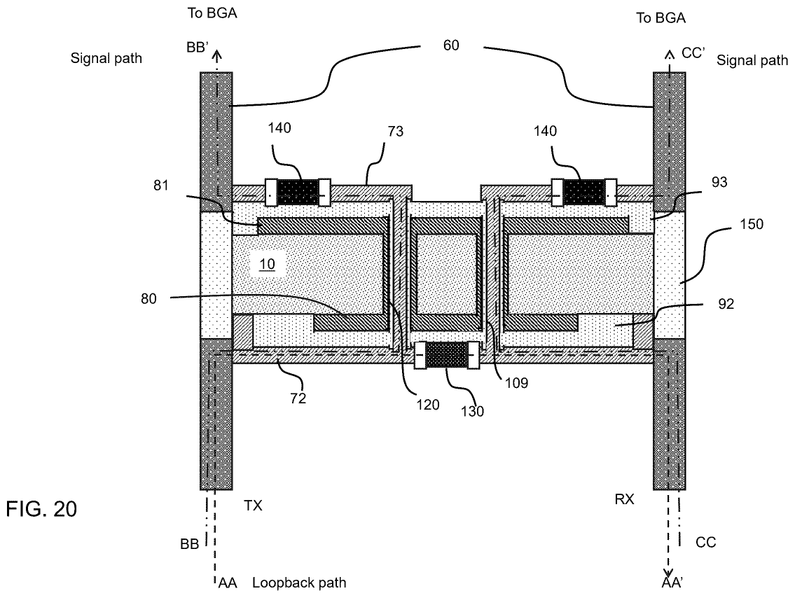

FIG. 16A shows a cross-sectional view of the intermediate integrated probe head, taken along the A-A′ axis of FIG. 16B and B-B′ axis of FIG. 16C, after forming the lower second conductive layer 72 trace for capacitor 130 placement. The high frequency loopback path AA-AA′ may be established between transmitter (TX as shown FIG. 20) and receiver (RX as shown FIG. 20) through the lower second conductive layer 72 and capacitor 130. Capacitor 130 may operate as a high pass filter in which high frequency signal passes through while low frequency signal does not.

FIG. 16B provides a top-down view of the intermediate integrated probe head, illustrating dielectric 93. FIG. 16C provides a bottom-up view of the intermediate integrated probe head after forming the lower second conductive layer 72 trace on a lower second dielectric 92.

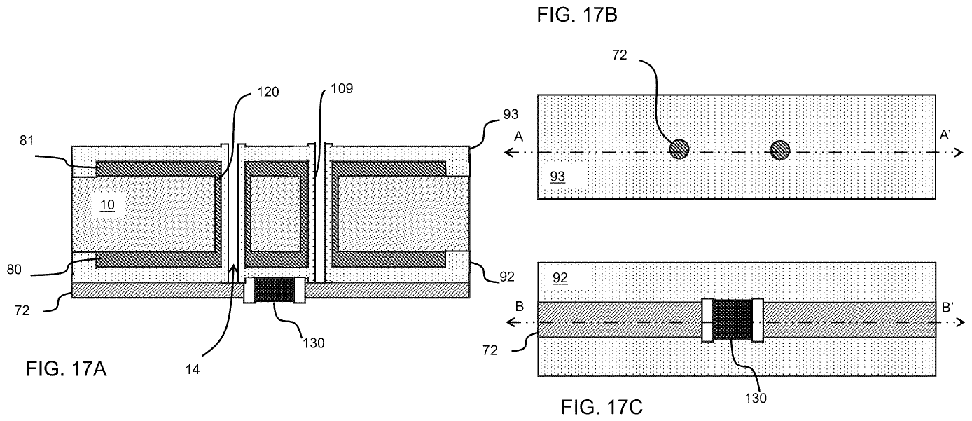

FIG. 17A illustrates a cross-sectional view of the intermediate integrated probe head, taken along the A-A′ axis of FIG. 17B and B-B′ axis of FIG. 17C, after etching oxide trench 14 following the lower second conductive layer 72 trace formation for capacitor 130 placement. The oxide etch process through patterning involves selectively removing dielectric oxide layers, such as silicon dioxide (SiO2), to expose underlying the lower second conductive layers 72 or create openings. This may be performed using, but not limited to, anisotropic plasma dry etching or laser ablation. Anisotropic etching may leave oxide barrier 109 covering GND shielding layer 120 while oxide trench 14 is created for metal fill.

FIG. 17B provides a top-down view of the intermediate integrated probe head. FIG. 17C provides a bottom-up view of the intermediate integrated probe head after capacitor 130 placement. The capacitor 130 may be placed using pick-and-place (PnP) equipment.

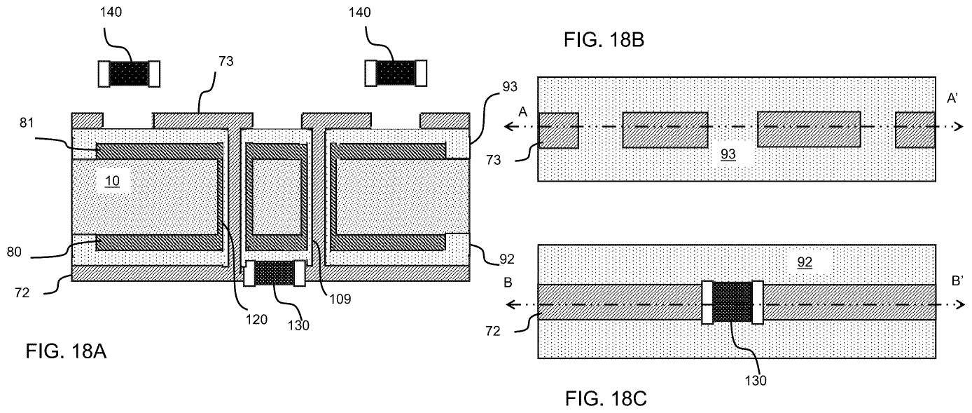

FIG. 18A illustrates a cross-sectional view of the intermediate integrated probe head, taken along the A-A′ axis of FIG. 18B and B-B′ axis of FIG. 18C, after depositing conductive layer 73, patterning, and etching the metal trace of conductive layer 73. Both second conductive layer 72 and 73 may be connected through oxide trench 14, as described in FIG. 17A. Patterning on conductive layer 73 may be designed to accommodate inductors 140 placement and meet routing requirements by various designs. Inductors 140 may operate as a low pass filter in which low frequency signal passes through while high frequency signal does not.

FIG. 18B provides a top-down view of the intermediate integrated probe head after patterning of conductive layer 73. FIG. 18C provides a bottom-up view of the intermediate integrated probe head.

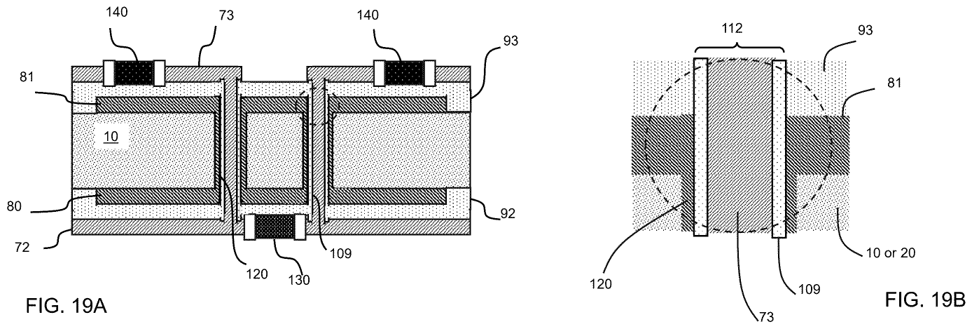

FIG. 19A illustrates a cross-sectional view on integrated probe head after inductor 140 and capacitor 130 placement. Having inductors 140 and capacitor 130, integrated probe head may transmit convoluted signals in which high frequency signals and low frequency signals co-exist, such that capacitor 130 permits the passage of high frequency signals and inductors 140 permits the passage of low frequency signals. While transmitting signals, GND shielding layer 120 may prevent crosstalk and unintentional electrical connections between conductive layers, improving overall signal isolation. GND shielding layer 120 may help mitigate EMI, ensuring that high-frequency signals experience minimal interference.

FIG. 19B provides a zoom-in view of via structure 112 comprising conductive layer 73 surrounded by an oxide barrier 109. The oxide barrier may isolate the via structure 112 from the adjacent conductive layers to prevent unintended electrical connection. Additionally, the GND shielding layer 120 may be positioned adjacent to the Via structure 112, while GND metal layers (80, 81) and GND shielding layer 120 are electrically connected. The GND shielding layer 120 may help to reduce electromagnetic interference (EMI) by providing a ground reference potential, thereby improving signal integrity across the structure.

The embodiment disclosed herein may offer several advantages for high-frequency operations. By incorporating oxide barriers 109 and GND shielding layers 120, the design may prevent crosstalk and unintentional electrical connections between conductive layers, improving overall signal isolation. GND shielding layer 120 may help mitigate EMI, ensuring that high-frequency signals experience minimal interference. Furthermore, the via structure 112, when insulated and shielded, may support efficient vertical signal routing for low frequency toward inductors while maintaining the integrity of both signal and power lines. Thus, the embodiment may enhance performance for applications demanding high signal integrity and power stability.

FIG. 20 illustrates a cross-sectional view of an integrated probe head with loopback needles 60. The loopback needle 60 is divided into two portions by dielectric material layer 150: the top portion connects to the BGA (ball grid array) for external signal routing, while the bottom portion is dedicated to the transmitter (TX) and receiver (RX). The high frequency loopback path (AA-AA′) may be established between transmitter (TX) and receiver (RX) through lower second conductive layer 72 and capacitor 130, while low frequency signal paths (BB-BB′ and CC-CC′) from TX and RX to BGA(ball grid array) are established through via structure 112 and inductor 140. The direct electrical connection between the loopback needles 60 and the lower second conductive layer 72 may effectively shorten the loopback signal path, thereby minimizing signal degradation and improving high frequency test performance.

FIG. 21 illustrates the guide holes (160, 162, 163) in ceramic plate dies 10. Loopback needle guide holes (160), GND needle guide hole (162), and power needle guide hole (163) may be plated with metal conductive materials. The choice of metal conductive material for the plating may include, but is not limited to, copper (Cu), gold (Au), nickel (Ni), or tungsten (W). These metals are selected based on their electrical conductivity, resistance to oxidation, and durability in high-frequency testing environments. For instance, gold may be preferred for resistance to corrosion, while copper may be favored for conductivity and cost-effectiveness. Tungsten may also be chosen for mechanical robustness for high-temperature applications. The plating process may involve electroplating or electroless plating techniques, where a thin metal layer is deposited uniformly on the inner surface of the guide holes. This ensures that the conductive layer is well-adhered, providing consistent electrical performance. The thickness of the plating may be controlled to meet the specific requirements of the probe system, ensuring durability and optimal electrical contact.

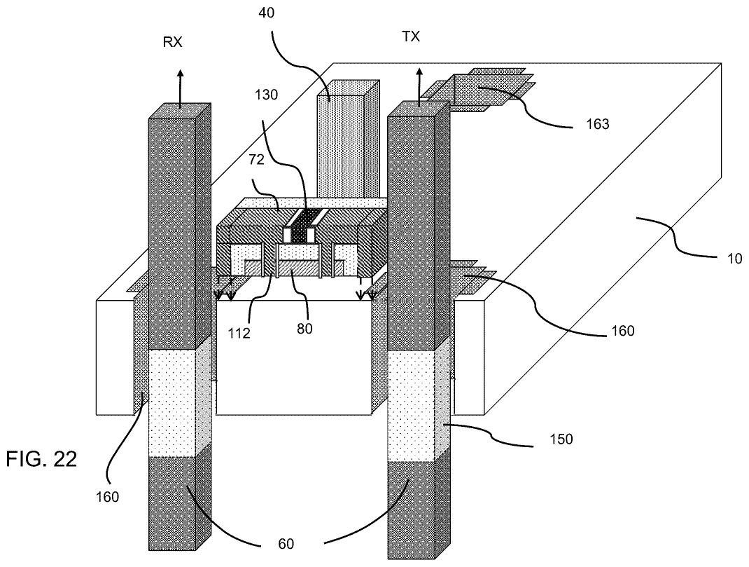

FIG. 22 illustrates an exploded perspective view of an integrated probe head assembly, including loopback needles 60. FIG. 22 helps to provide additional clarity on how the components described in FIG. 20 are assembled with loopback needles 60 and guide holes 160 in a ceramic plate dies 10, such that loopback needles 60 and metal plated guide holes 160 may be electrically connected to the second conductive layer 72 deposited on the lower surface of the ceramic plate die 10. The plated guide hole 160 may provide a conductive path that connects and shorts the two loopback needles 60 together through lower second conductive layer 72 and capacitor 130, such that the shortened high frequency loopback path, as compared to the conventional path through MLO in FIG. 1, may be established between transmitter (TX) and receiver (RX) through the lower second conductive layer 72 and capacitor 130. The embodiment disclosed herein addresses signal instability challenges by shortening high frequency loopback path, thereby minimizing signal degradation and maintaining the accuracy required for probe testing at high frequencies, ensuring reliable and high-performance testing environments.

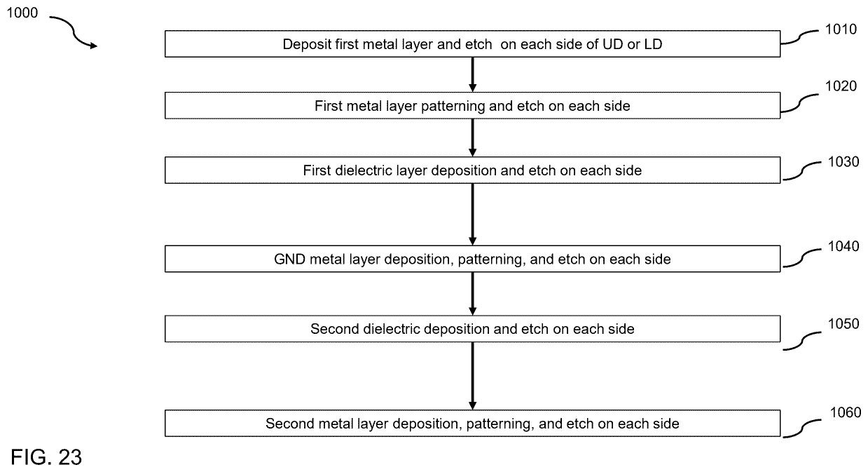

FIG. 23 is a process flowchart (1000) that illustrates the method steps to form an impedance control stack-up structure on a ceramic plate dies 10 for high-frequency probing applications. Referring to FIGS. 1, 2, and 23, the process begins with step 1010, where a first conductive layer (70, 71) is deposited on both sides of the ceramic plate dies 10. In step 1020, the first conductive layer (70, 71) may be patterned and etched on each side of the ceramic plate dies 10 to form a signal or power trace.

In step 1030, a first dielectric layer (90, 91) may be deposited over the patterned first conductive layer (70, 71) on both sides of the ceramic plate dies 10. The dielectric layer may include materials such as silicon dioxide (SiO2), silicon nitride (Si3N4), or SiCOH, optimizing the impedance by controlling dielectric constant and thickness. In step 1040, a GND metal layer (80, 81) may be deposited on each side, followed by patterning and etching, such that GND metal layer (80, 81) creates a ground path through a GND Shielding layer 120 to reduce electromagnetic interference (EMI).

In step 1050, a second dielectric layer (92, 93) may be deposited over the patterned GND metal layer (80, 81) on each side of ceramic plate dies 10, followed by patterning and etch. The dielectric layer may include materials such as silicon dioxide (SiO₂), silicon nitride (Si₃N₄), or SiCOH, optimizing the impedance by controlling dielectric constant and thickness.

In step 1060, a second conductive layer (72, 73) may be deposited, patterned and etched on each side of the ceramic plate dies 10 to form a signal or power trace.

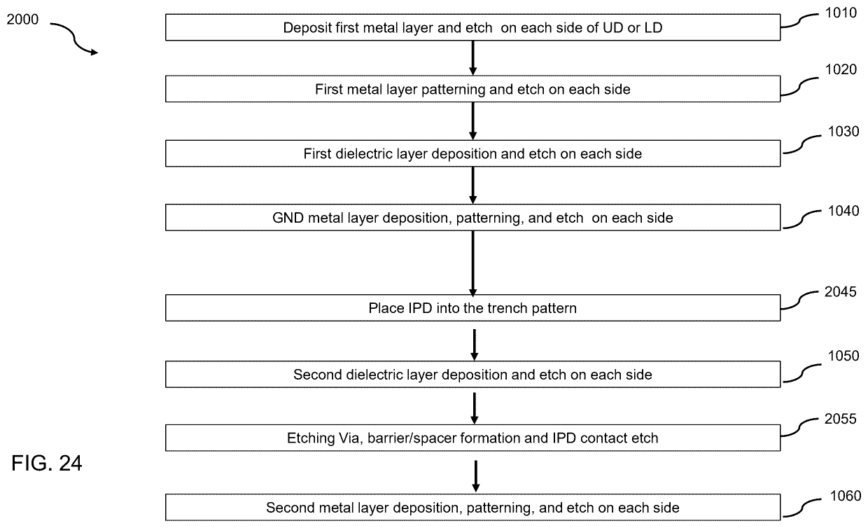

FIG. 24 is a process flowchart (2000) that illustrates the method steps to form an impedance control stack-up structure with IPD (100, 101) integration on a ceramic plate dies 10 for high-frequency probing applications. For brevity, details about repeating steps 1010 to 1040 are omitted or reduced. Referring to FIGS. 3A to 10B, the process begins with step 1010, followed by subsequent steps (1020, 1030, 1040). In step 2045, placing IPD (100, 101) may be performed into the trench pattern. In step 1050, a second dielectric layer (92, 93) may be deposited over the patterned GND metal layer (80, 81) on each side of ceramic plate dies 10, followed by patterning and etch. The dielectric layer may include materials such as silicon dioxide (SiO2), silicon nitride (Si3N4), or SiCOH, optimizing the impedance by controlling dielectric constant and thickness.

In 2055, an additional etching process for via formation may be performed, including barrier formation followed by IPD (100, 101) contact etch process. In step 1060, a second conductive layer (72, 73) may be deposited, patterned and etched on each side of the ceramic plate dies 10 to form a signal or power trace.

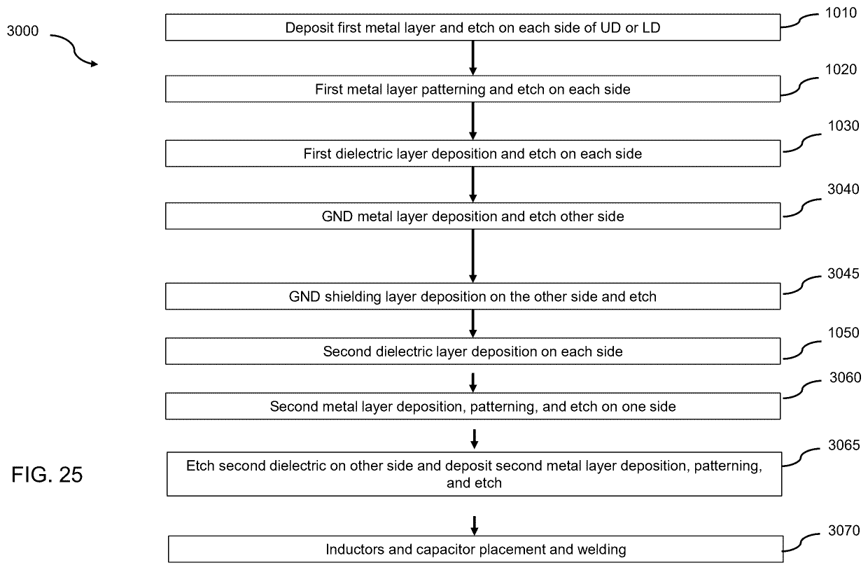

FIG. 25 is a process flowchart (3000) that illustrates the method steps to form an integrated probe head with impedance control stack-up structure on a ceramic plate dies 10 for high-frequency probing applications. For brevity, details about repeating step 1010 to step 1030 are omitted or reduced. Referring to FIGS. 11A to 20, the process begins with step 1010, followed by subsequent steps (1020, 1030). In step 3040, GND metal layer (80, 81) may be deposited on ceramic directly where the probe head gets integrated, and where material deposition and etch steps (1020, 1030) may be performed to clean the ceramic surface. Subsequently, ceramic etch may be performed to form GND shielding trench 12 as shown in FIG. 12A. Following deposition and pattern etching, GND shielding layer 120 may be formed during the deposition of GND metal 81 as shown in FIG. 13A. GND metal layer (80, 81) may be etched in step 3045 as shown in FIGS. 14A-14C, such that GND metal layer makes direct contact to GND metal layer. In step 1050, referring to FIG. 15A, a second dielectric layer (92, 93) may be deposited over the patterned GND metal layer (80, 81) on each side of ceramic plate dies 10, followed by patterning and etch. The dielectric layer may include materials such as silicon dioxide (SiO₂), silicon nitride (Si₃N₄), or SiCOH, optimizing the impedance by controlling dielectric constant and thickness.

In step 3060, referring to FIG. 16A, a second conductive layer (72, 73) may be deposited, patterned and etched on one side of the ceramic plate dies 10 to form a signal or power trace with capacitor placement.

In step 3065, referring to FIG. 17A, etching dielectric 93 may be performed to form oxide trench 14 while oxide barrier 109 may be covering side wall of GND shielding layer 120. Subsequently, a upper second conductive layer 73 deposition, patterning and etch may follow, such that inductor 140 may be configured, in step 3070, to establish signal path to BGA.

According to various embodiments of the present disclosure, this impedance control stack-up structure addresses high frequency test challenges by incorporating an impedance controlled stack-up structure on ceramic plate dies 10 where integrated passive devices IPD (100, 101), LC devices 140, 130 GND shielding layer 120 are embedded, ensuring precise impedance control, minimizing EMI, and achieving a shortened loopback path for high frequency testing.

Referring to all the drawings and according to various embodiments of the present disclosure, a semiconductor structure may be provide wherein the semiconductor structure, includes a ceramic plate die 10 having an upper surface; a conductive layer 70, 71 formed on the upper surface of the ceramic plate die 10; a dielectric layer formed over the first conductive layer 70, 71, wherein a thickness and a dielectric constant of the dielectric layer 90, 91 is configured to modulate an impedance of the stack-up structure.

In some embodiments, the semiconductor structure further includes a guide hole 160, 161, 162, 163 located in the ceramic plate die 10, in which the guide hole 160, 161, 162, 163 may be configured to connect a pair of loopback needles 60. In one embodiment, a surface area of the conductive layer 70, 71 may be configured to modulate the impedance of the stack-up structure. In one embodiment, the dielectric layer 90, 91 may include one of SiO2, Si3N4, SiCOH, SiLK, or polyimide. In one embodiment, the semiconductor structure further includes a ground (GND) metal layer 80, 81 formed over the dielectric layer 90, 91, in which a surface area of the GND metal layer 80, 81 may be configured to modulate the impedance of the stack-up structure. In one embodiment, the semiconductor device further includes a GND shielding layer such that the GND shielding layer 120 may be electrically connected to the GND metal layer 80, 81. In one embodiment, the semiconductor structure further includes a second dielectric layer 92, 93 formed on the GND metal layer, in which a surface area of the second conductive layer 92, 93 may be configured to modulate the impedance of the stack-up structure. In one embodiment, the semiconductor device further includes a bottom conductive layer 92, 93 formed on a lower surface of the ceramic plate die 10. In one embodiment, the semiconductor structure further includes a via structure 110, 112, in which the via structure 110, 112 includes a metal core 72, 73 surrounded by a barrier dielectric 107, 108, such that the metal core 72, 73 connects vertically between the conductive layer on of the upper surface of the ceramic plate die 10 and the bottom conductive layer 72, 73 on the lower surface of the ceramic plate die 10.

According to another aspect of the present disclosure, a method of forming an integrated impedance control stack-up structure is provided, wherein the method includes: plating a metal over a guide hole (160, 161, 162, 163) in ceramic plate die 10, wherein the ceramic plate die 10 has an upper surface and a lower surface; depositing a first conductive layer 70, 71 on at least one of the upper surface or the lower surface of ceramic plate die 10; patterning and etching the first conductive layers 70, 71; depositing a first dielectric layer 90, 91 over the first conductive layers 70, 71 on at least one of the upper surface or the lower surface of ceramic plate die 10, the first dielectric layers 90, 91 having a specified thickness and dielectric constant.

In one embodiment, the method may also include: depositing a GND (ground) metal layer 80, 81 over the first dielectric layers 90, 91 on at least one of the upper surface or the lower surface of ceramic plate die 10; patterning and etching the GND metal layers 80, 81; depositing a second dielectric layer 92, 93 formed over the GND metal layers 80, 81 on at least one of the upper surface or the lower surface of ceramic plate die 10; depositing a second conductive layer 72, 73 over the second dielectric layers 92, 93 on at least one of the upper surface or the lower surface of ceramic plate die 10; patterning and etching the second conductive layers 72, 73; and forming a via structure 110, 112 extending through the first dielectric layer 90, 91 and second dielectric layer 92, 93 to electrically couple one of the first conductive layer 70, 71 to one of the second conductive layers 72, 73, wherein forming the via structure 110, 112 comprises: etching through a stack of the first conductive layer 70, 71, the first dielectric layer 90, 91, the GND metal layer 80, 81, and the second dielectric layer 92, 93; and forming a barrier dielectric 107, 108, wherein the barrier dielectric 107, 108 encloses the via structure 110, 112. In one embodiment, the method may further include: forming a GND shielding layer 120 by etching a cavity through the ceramic plate die 10 and depositing the GND metal layer 80, 81 through the cavity. In one embodiment, the GND shielding layer 120 surrounds the via structure 110, 112 and makes a direct contact to the GND metal layer 80, 81.

According to another aspect of the present disclosure, a semiconductor structure may include a stack up structure including: a ceramic plate die 10; a conductive layer 70, 71 formed on a surface of the ceramic plate die 10; and a dielectric layer 90, 91 formed over the conductive layer 70, 71; an integrated passive device (IPD) 140 embedded within the stack-up structure; an integrated LC device embedded within the stack-up structure; and an dielectric material layer 160 configured to divide a conducting loopback needle 60 into two distinct, electrically insulated portions.

In an embodiment, the semiconductor structure further includes a metal plated guide hole 160, 161, 162, 163 electrically connects a pair of loopback needles through the conductive layer on the surface of the ceramic plate die 10 and a metal trace connection to the guide hole 160, 161, 162, 163. In one embodiment, the semiconductor structure further includes a ground (GND) metal layer 80, 81 formed on an upper surface of the ceramic plate die 10, in which a surface area of the GND metal layer is configured to modulate a capacitance and an impedance in the stack-up structure. In one embodiment, a dielectric constant and a thickness of the dielectric layer 92, 93 is configured to modulate a capacitance and an impedance in the stack-up structure. In one embodiment, a surface area of the conductive layer 72, 73 is configured to modulate a capacitance and an impedance in the stack-up structure. In one embodiment, the LC device includes a capacitor 130 configured to form a loopback path through the conductive layer 72, 73, the capacitor 130, and the loopback needle 60 to a device under test. In one embodiment, the LC device further includes an inductor 140 configured to form a signal path through the conductive layer 72, 73 and the loopback needle 60 to a BGA board.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a ceramic plate die having an upper surface;
a conductive layer formed on the upper surface of the ceramic plate die; and
a dielectric layer formed over the first conductive layer, wherein a thickness and a dielectric constant of the dielectric layer is configured to modulate an impedance of the semiconductor structure.

2. The semiconductor structure of claim 1, further comprising a guide hole located in the ceramic plate die, wherein the guide hole is configured to connect a pair of loopback needles.

3. The semiconductor structure of claim 1, wherein a surface area of the conductive layer is configured to modulate the quantity of the impedance of the stack-up structure.

4. The semiconductor structure of claim 1, further comprising a ground (GND) metal layer formed over the dielectric layer, wherein a surface area of the GND metal layer is configured to modulate the impedance of the stack-up structure.

5. The semiconductor structure of claim 4, further comprising a GND shielding layer such that the GND shielding layer is electrically connected to the GND metal layer.

6. The semiconductor structure of claim 4, further comprising a second dielectric layer formed on the GND metal layer, wherein a surface area of the second conductive layer is configured to modulate the impedance of the stack-up structure.

7. The semiconductor structure of claim 1, further comprising a bottom conductive layer formed on a lower surface of the ceramic plate die.

8. The semiconductor structure of claim 7, further comprising a via structure, wherein the via structure includes a metal core surrounded by a barrier dielectric, such that the metal core connects vertically between the conductive layer on the upper surface of the ceramic plate die and the bottom conductive layer on the lower surface of the ceramic plate die.

9. The semiconductor structure of claim 7, further comprising:
a GND metal layer formed over the dielectric layer;
a second dielectric layer formed over the GND layer;
a second conductive layer formed over the second dielectric layer;
a bottom dielectric layer formed over the bottom conductive layer;
a bottom GND metal layer formed over the bottom dielectric layer;
a second bottom dielectric layer formed over the bottom GND layer; and
a second bottom conductive layer formed over the second bottom dielectric layer.

10. A method of forming an integrated impedance control stack-up structure comprising:
plating a metal over a guide hole in a ceramic plate die, wherein the ceramic plate die has an upper surface and a lower surface;
depositing a first conductive layer on at least one of the upper surface or the lower surface of ceramic plate die;
patterning and etching the first conductive layers; and
depositing a first dielectric layer over the first conductive layers on at least one or the upper surface or the lower surface of ceramic plate die, the first dielectric layers having a specified thickness and dielectric constant.

11. The method of claim 10, further comprising:
depositing a GND (ground) metal layer over the first dielectric layers on at least one of the upper surface or the lower surface of ceramic plate die;
patterning and etching the GND metal layers;
depositing a second dielectric layer formed over the GND metal layers on at least one of the upper surface or the lower surface of ceramic plate die;
depositing a second conductive layer over the second dielectric layers on at least one of the upper surface or the lower surface of ceramic plate die;
patterning and etching the second conductive layers; and
forming a via structure extending through the dielectric layers to electrically couple one of the first conductive layers to one of the second conductive layers wherein the forming the via structure comprises:
etching through a stack of the first conductive layer, the first dielectric layer, the GND metal layer, and the second dielectric layer; and
forming a barrier dielectric, wherein the barrier dielectric encloses the via structure.

12. The method of claim 11, further comprises:
forming a GND shielding layer by etching a cavity through the ceramic plate die and depositing the GND metal layer through the cavity.

13. The method of claim 12, wherein the GND shielding layer surrounds the via structure and makes a direct contact to the GND metal layer.

14. A semiconductor structure, comprising:
a stack up structure comprising:
a ceramic plate die;
a conductive layer formed on a surface of the ceramic plate die; and
a dielectric layer formed over the conductive layer;
an integrated passive device (IPD) embedded within the stack-up structure;
an integrated LC device embedded within the stack-up structure; and
a dielectric material layer configured to divide a conducting loopback needle into two distinct, electrically insulated portions.

15. The impedance control stack-up structure of claim 14, further comprising a metal plated guide hole, wherein the metal plated guide hole electrically connects a pair of loopback needles through the conductive layer on the surface of the ceramic plate die and a metal trace connection to the guide hole.

16. The impedance control stack-up structure of claim 14, further comprising a ground (GND) metal layer formed on an upper surface of the ceramic plate die, wherein a surface area of the GND metal layer is configured to modulate a capacitance and an impedance in the stack-up structure.

17. The impedance control stack-up structure of claim 14, wherein a dielectric constant and a thickness of the dielectric layer is configured to modulate a capacitance and an impedance in the stack-up structure.

18. The impedance control stack-up structure of claim 14, wherein a surface area of the conductive layer is configured to modulate a capacitance and an impedance in the stack-up structure.

19. The impedance control stack-up structure of claim 14, wherein the LC device includes a capacitor configured to form a loopback path through the conductive layer, the capacitor, and the loopback needle to a device under test.

20. The impedance control stack-up structure of claim 14, wherein the LC device further includes an inductor configured to form a signal path through the conductive layer and the loopback needle to a BGA board.
